(19) United States
(12) Patent Application Publication
(10) Pub. No.: US 2014/0306331 A1
(43) Pub. Date: Oct. 16, 2014

(54) CHIP AND CHIP ARRANGEMENT

(71) Applicant: INFINEON TECHNOLOGIES AUSTRIA AG, Villach (AT)

(72) Inventors: Ralf Otremba, Kaufbeuren (DE); Josef Hoeglauer, Heimstetten (DE); Juergen Schredl, Mering (DE); Xaver Schloegel, Sachsenkam (DE); Klaus Schiess, Allensbach (DE)

(73) Assignee: Infineon Technologies Austria AG, Villlach (AT)

(21) Appl. No.: 13/860,538

(22) Filed: Apr. 11, 2013

(51) Int. Cl. H01L 23/34

(52) U.S. Cl. CPC H01L 23/34
USPC 257/676; 257/734; 438/597

(57) ABSTRACT

Various embodiments provide a chip. The chip may include a body having two main surfaces and a plurality of side surfaces; a first power electrode extending over at least one main surface and at least one side surface of the body; and a second power electrode extending over at least one main surface and at least one side surface of the body.

### TECHNICAL FIELD

Various embodiments relate generally to a chip, a chip arrangement, and a method for manufacturing the same.

### BACKGROUND

Power semiconductor chips may be integrated into an electronic package, e.g. a through-hole-package (THP) or a surface-mounted-device (SMD).

FIG. 1 shows a conventional power package 100, including a leadframe 102 and a chip 104 attached on the leadframe 102 through solder wire 106. The re-distribution or re-wiring of the chip 104 is carried out by bond wire 108. Mold compound 110 encapsulates the chip 104 and the leadframe 102 to form the power package 100. However, this kind of power package may have limitation in electrical performance (e.g. maximum current carrying capability of the bond wire) and thermal performance.

In some approaches, bond wires, e.g., in the power package 100, are replaced by means of clips or by means of galvanic re-distribution or re-wiring. These measures may improve the maximum current carrying capability due to the increase of the cross-section. However, the thermal chip limitation remains comparable to the bond wire re-distribution, since this is dominated by the leadframe (LF) and the corresponding chip connection.

### SUMMARY

Various embodiments provide a chip. The chip may include a body having two main surfaces and a plurality of side surfaces; a first power electrode extending over at least one main surface and at least one side surface of the body; and a second power electrode extending over at least one main surface and at least one side surface of the body.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a conventional power package;

FIG. 2 shows a chip according to various embodiments;

FIG. 3 shows a chip according to various embodiments;

FIG. 4 shows a chip arrangement according to various embodiments;

FIG. 5 shows a chip arrangement according to various embodiments;

FIG. 6 shows a chip arrangement according to various embodiments;

FIG. 7 shows a chip arrangement according to various embodiments;

FIG. 8A shows a conventional chip arrangement;

FIG. 8B shows a chip arrangement according to various embodiments;

FIG. 9A shows a chip arrangement according to various embodiments;

FIG. 9B shows a cascade circuit according to various embodiments;

FIG. 10 shows a flowchart illustrating a method of manufacturing a chip according to various embodiments; and

FIG. 11 shows a flowchart illustrating a method of manufacturing a chip arrangement according to various embodiments.

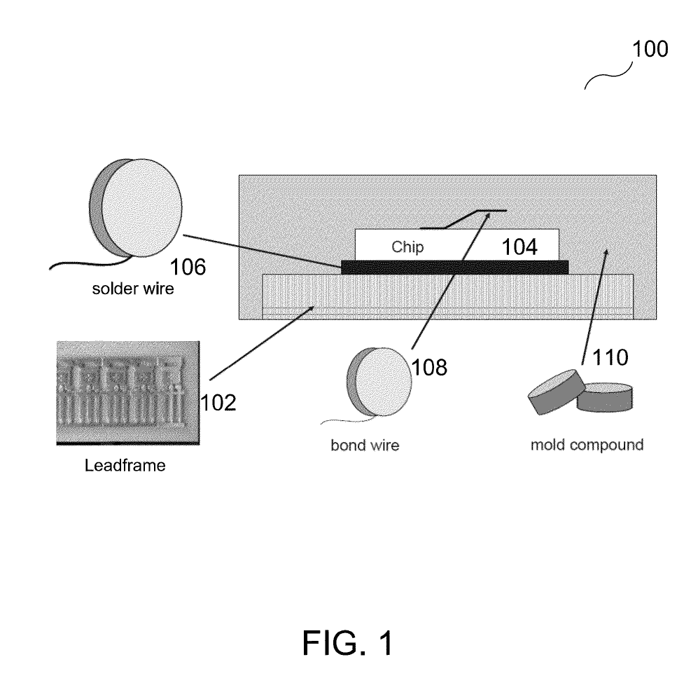

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

Various embodiments may provide a chip and a chip arrangement, in which the chip re-wiring or re-distribution is improved electrically and thermally for a power chip package. Various embodiments may provide a three-dimensional (3D) Chip-Redistribution for power packages.

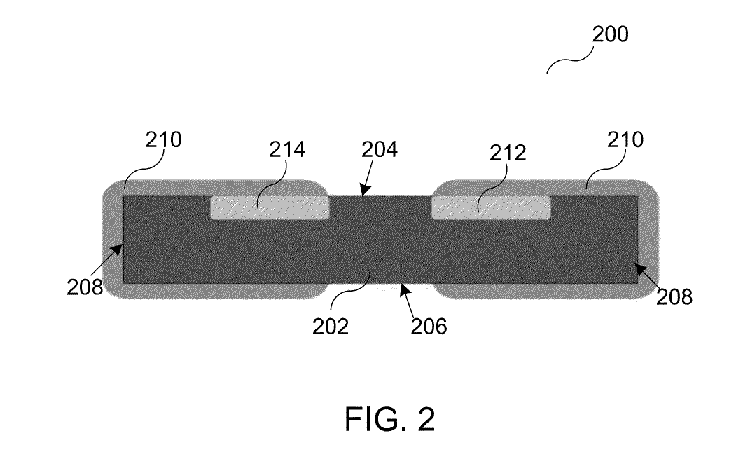

FIG. 2 shows a chip 200 according to various embodiments.

The chip 200 may include a body 202 having two main surfaces 204, 206 (e.g. the top main surface 204 and the bottom main surface 206) and a plurality of side surfaces 208.

The chip 200 may further include a first power electrode 212 extending over at least one main surface 204, 206 and at least one side surface 208 of the body 202; and a second power electrode 214 extending over at least one main surface 204, 206 and at least one side surface 208 of the body. In the embodiments shown in FIG. 2, the first power electrode 212 and the second power electrode 214 may extend over both main surface 204, 206. However, it is understood that the first power electrode 212 and the second power electrode 214 may extend over only one of the two main surfaces 204, 206.

In various embodiments, at least one of the first power electrode 212 and the second power electrode 214 may extend over at least a portion of a plurality of the side surface 208 of the body 202.

In various embodiments, at least one of the first power electrode 212 and the second power electrode 214 may extend over a portion of both main surfaces 204, 206 of the body 202.

In various embodiments, at least one of the first power electrode 212 and the second power electrode 214 may extend over at least one main surface 204, 206 and at least one side surface 208 of the body through a solderable layer 210.

In various embodiments, the first power electrode 212 and the second power electrode 214 may have a symmetric arrangement. For example, as shown in FIG. 2, the first power electrode 212 and the second power electrode 214 are symmetrically arranged on the main surface 204 of the body.

At least one of the first power electrode 212 and the second power electrode 214 may be made of a metal such as e.g. a metal selected from a group of metals consisting of: Cu, Ni, Ti, Au, Ag, Pd, Pt, W.

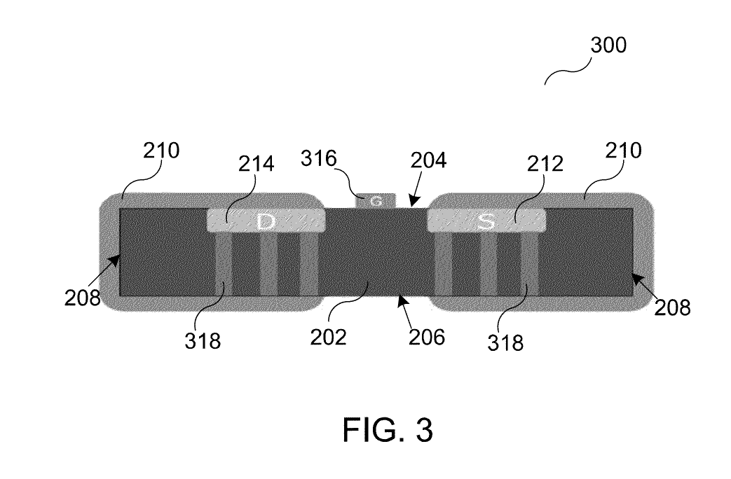

FIG. 3 shows a chip 300 according to various embodiments.

Similar to the chip 200 of FIG. 2, the chip 300 may include a body 202 having two main surfaces 204, 206 (e.g. the top main surface 204 and the bottom main surface 206) and a plurality of side surfaces 208. The chip 300 may further include a first power electrode 212 extending over at least one main surface 204, 206 and at least one side surface 208 of the body 202; and a second power electrode 214 extending over at least one main surface 204, 206 and at least one side surface 208 of the body.

Similar to various embodiments of FIG. 2, the first power electrode 212 and the second power electrode 214 of the chip 300 may extend over one or both of the two main surfaces 204, 206. In various embodiments, at least one of the first power electrode 212 and the second power electrode 214 of the chip 300 may extend over at least a portion of a plurality of the side surface 208 of the body 202. In various embodiments, at least one of the first power electrode 212 and the second power electrode 214 of the chip 300 may extend over a portion of both main surfaces 204, 206 of the body 202. Similar to various embodiments of FIG. 2, at least one of the first power electrode 212 and the second power electrode 214 of the chip 300 may extend over at least one main surface 204, 206 and at least one side surface 208 of the body through a solderable layer 210.

Similar to various embodiments of FIG. 2, the first power electrode 212 and the second power electrode 214 of the chip 300 may have a symmetric arrangement. At least one of the first power electrode 212 and the second power electrode 214 of the chip 300 may be made of a metal selected from a group of metals consisting of: Cu, Ni, Ti, Au, Ag, Pd, Pt, W.

According to various embodiments, the chip 300 may be configured as a power transistor.

In various embodiments, the chip 300 may further include a control electrode 316 of the power transistor. In various embodiments, the control electrode 316 and both power electrodes 212, 214 may be arranged on the same main surface of the body 202, e.g. on the main surface 204. In various embodiments, the control electrode 316 may also be arranged on the other main surface of the body 202 than the power electrodes 212, 214, e.g. on the other main surface 206.

According to various embodiments, the chip 300 may be configured as a power field effect transistor, e.g., a power MOSFET (metal oxide semiconductor field effect transistor) or a JFET (junction field effect transistor). The first power electrode 212 may be a source electrode (e.g. denoted by S in FIG. 3), the second power electrode 214 may be a drain electrode (e.g. denoted by D in FIG. 3), and the control electrode 316 may be a gate electrode (e.g. denoted by G in FIG. 3).

According to various embodiments, the chip 300 may be configured as a bipolar transistor. The first power electrode 212 may be an emitter electrode, the second power electrode 214 may be a collector electrode, and the control electrode 316 may be a base electrode.

According to various embodiments, the chip 300 may be configured as an insulated gate bipolar transistor (IGBT). The first power electrode 212 may be an emitter electrode, the second power electrode 214 may be a collector electrode, and the control electrode 316 may be a gate electrode.

In various embodiments, the chip may be configured as various power components, such as High Electron Mobility Transistors (HEMT), e.g., GaN (Gallium Nitride) HEMT, SiC (Silicon Carbide) HEMT, or High-voltage Si (Silicon) HEMT; or low-voltage (e.g., smaller than 200V) MOSFET (p-channel or n-channel), e.g. SFET (silicon field effect transistor).

According to various embodiments, the chip 300 may further include a plurality of through holes or vias 318 extending from at least one of the first power electrode 212 and the second power electrode 214 through the body 202 to the other main surface 206 of the body 202, wherein the vias may be filled with or include electrically conductive material such as e.g. metal such as e.g. Cu.

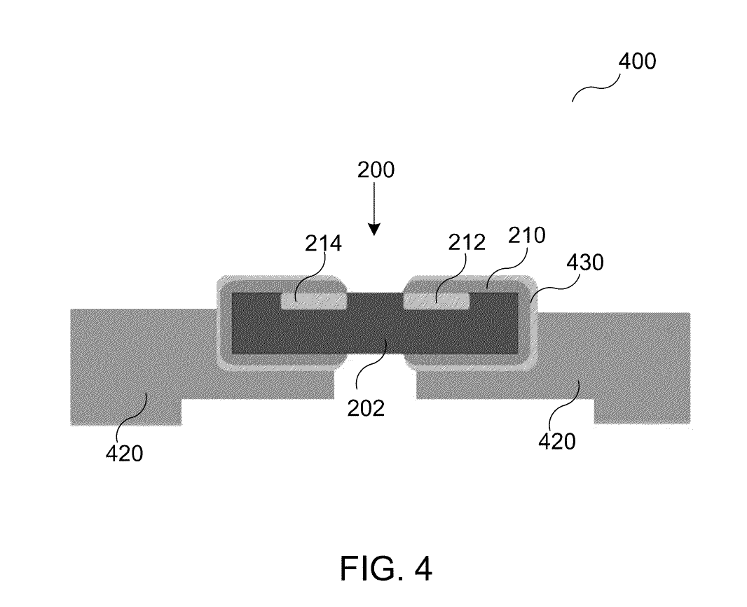

FIG. 4 shows a chip arrangement according to various embodiments.

As shown in FIG. 4, the chip arrangement 400 may include a chip carrier 420 and a chip 200 arranged over the chip carrier 420.

The chip 200 may have the same structure as the chip 200 of FIG. 2. As shown in FIG. 4, the chip 200 may include a body 202 having two main surfaces (e.g. the top main surface and the bottom main surface) and a plurality of side surfaces; a first power electrode 212 extending over at least one main surface and at least one side surface of the body 202; and a second power electrode 214 extending over at least one main surface and at least one side surface of the body 202. Various embodiments of the chip 200 described above are analogously valid for the chip arrangement 400.

In various embodiments, at least one of the first power electrode 212 and the second power electrode 214 may extend over at least one main surface and at least one side surface of the body 202 through a solderable layer 210.

In various embodiments, the chip 200 may be attached to the chip carrier 420 through a solder layer 430. In various embodiments, the solder layer 430 may be formed over the solderable layer 210 of the chip 200, so as to attach the chip 200 to the chip carrier 420.

According to various embodiments, the chip carrier 420 may be one of an FR4 substrate; a direct copper bond (DCB) substrate; and an isolated metal substrate (IMS), for example.

In various embodiments, the chip carrier 420 may be a leadframe. The leadframe may be made of a metal or a metal alloy, e.g. including a material selected from a group consisting of: copper (Cu), iron nickel (FeNi), steel, and the like. In various embodiments, the chip carrier 420 may be a structured leadframe. The leadframe may be structured to include a plurality of portions or blocks separate from each other, and/or may be structured to provide a desired creepage distance, which may be pre-defined, e.g. depending on the characteristics of the chip 200.

According to various embodiments, the chip 200 may be a bare chip (which may also be referred to as bare die) which is an integrated circuit cut out from the wafer and is ready for packaging.

In various embodiments, the chip arrangement 400 may further include encapsulating material encapsulating the chip carrier 420 and the chip 200, as will be described in more detail below.

In the embodiments of FIG. 400, the chip 200 is included in the chip arrangement 400. It is understood that the chip 300 described in FIG. 3 above may also be included in the chip arrangement.

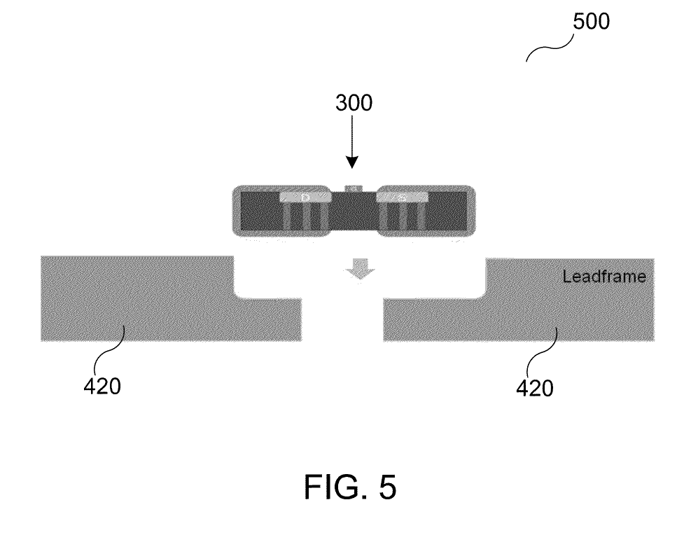

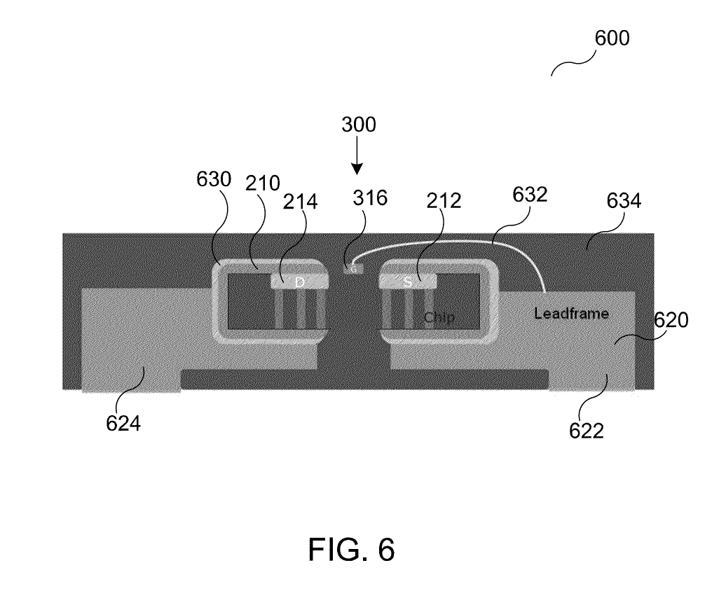

FIG. 5 shows a chip arrangement 500 according to various embodiments, in which the chip 300 of FIG. 3 is soldered into the opening of the chip carrier 420 (e.g. the leadframe). The thus formed chip arrangement 500 may be further encapsulated with encapsulation material as shown in FIG. 6 below.

FIG. 6 shows a chip arrangement 600 according to various embodiments. The chip arrangement 600 may include a chip carrier 620 and a chip 300 (e.g. the chip 300 of FIG. 3) arranged over the chip carrier 620.

The chip 300 may have the same structure as the chip 300 of FIG. 3. As shown in FIG. 6, the chip 300 may include a body having two main surfaces (e.g. the top main surface and the bottom main surface) and a plurality of side surfaces; a first power electrode 212 extending over at least one main surface and at least one side surface of the body; a second power electrode 214 extending over at least one main surface and at least one side surface of the body; and a control electrode 316 arranged on one of the main surfaces of the body.

In the embodiments of FIG. 6, the chip 300 may be configured as a power field effect transistor, e.g., a power MOSFET (metal oxide semiconductor field effect transistor) or a JFET (junction field effect transistor). The first power electrode 212 may be a source electrode (e.g. denoted by S in FIG. 6), the second power electrode 214 may be a drain electrode (e.g. denoted by D in FIG. 6), and the control electrode 316 may be a gate electrode (e.g. denoted by G in FIG. 6). According to various embodiments, the chip 300 may also be configured as a bipolar transistor or an insulated gate bipolar transistor.

In various embodiments, the control electrode 316 of the chip 300 may be re-wired or re-distributed to the chip carrier 620 via bond wire 632.

Various embodiments of the chip 300 described above are analogously valid for the chip arrangement 600.

In various embodiments, at least one of the first power electrode 212 and the second power electrode 214 may extend over at least one main surface and at least one side surface of the body through a solderable layer 210. A solder layer 630 may be formed over the solderable layer 210 of the chip 300, so as to attach or solder the chip 300 to the chip carrier 620 (e.g. a leadframe).

Similar to various embodiments described above, the chip carrier 620 may be one of an FR4 substrate; a direct copper bond (DCB) substrate; and an isolated metal substrate (IMS). In various embodiments, the chip carrier 620 may be a leadframe. The leadframe may be made of a metal or a metal alloy, e.g. including a material selected from a group consisting of: copper (Cu), iron nickel (FeNi), steel, and the like. In various embodiments, the chip carrier 620 may be a structured leadframe. The leadframe may be structured to include a plurality of portions or blocks separate from each other, and/or may be structured to provide a desired creepage distance.

According to various embodiments, the chip 300 may be a bare chip which is an integrated circuit cut out from the wafer and is ready for packaging.

In various embodiments, the chip arrangement 600 may further include encapsulating material 634 encapsulating the chip carrier 620 and the chip 300, as e.g. shown in FIG. 6. The encapsulating material 634 may include mold compound, such as filled epoxy (e.g. epoxy filled with SiO), or may include a laminate. The chip arrangement 600 may also be referred to as a chip package 600.

According to various embodiments, a chip arrangement adapted to customer requirements (e.g. requirement on creepage distance) may be provided or manufactured by means of a structured leadframe, e.g., a both-side (double-sided) structured leadframe. By way of example, the embodiments of FIG. 6 show a structured leadframe 620 with a desired distance between the first power electrode 212 and the second power electrode 214, e.g. the distance between the respective leadframe portions 622, 624 electrically coupled to the power electrodes 212, 214, respectively. The respective leadframe portions 622, 624 may be further coupled to respective leads for electrical connection with other chips or components.

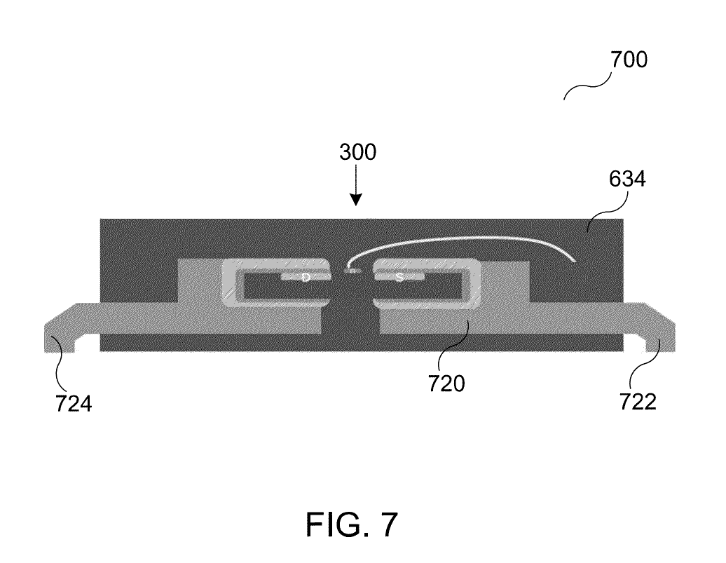

FIG. 7 shows a chip arrangement 700 similar to the chip arrangement 600, wherein the chip arrangement 700 includes a chip carrier 720, the chip 300 arranged over the chip carrier 720, and encapsulating material 634 encapsulating the chip carrier 720 and the chip 300. Various embodiments described in the chip arrangement 600 above are analogously valid for the chip arrangement 700.

Different from the chip arrangement 600, the chip arrangement 700 includes a structured leadframe 720 as the chip carrier. The structured leadframe 720 may be structured such that the distance between both power electrodes, e.g. the distance between the respective leadframe portions 722, 724 electrically coupled to the power electrodes, are further increased, compared with the leadframe 620 of FIG. 6. In the embodiments of FIG. 7, the chip arrangement 700 with significantly increased distance between both power electrodes may be used for high volt products (e.g. >200V).

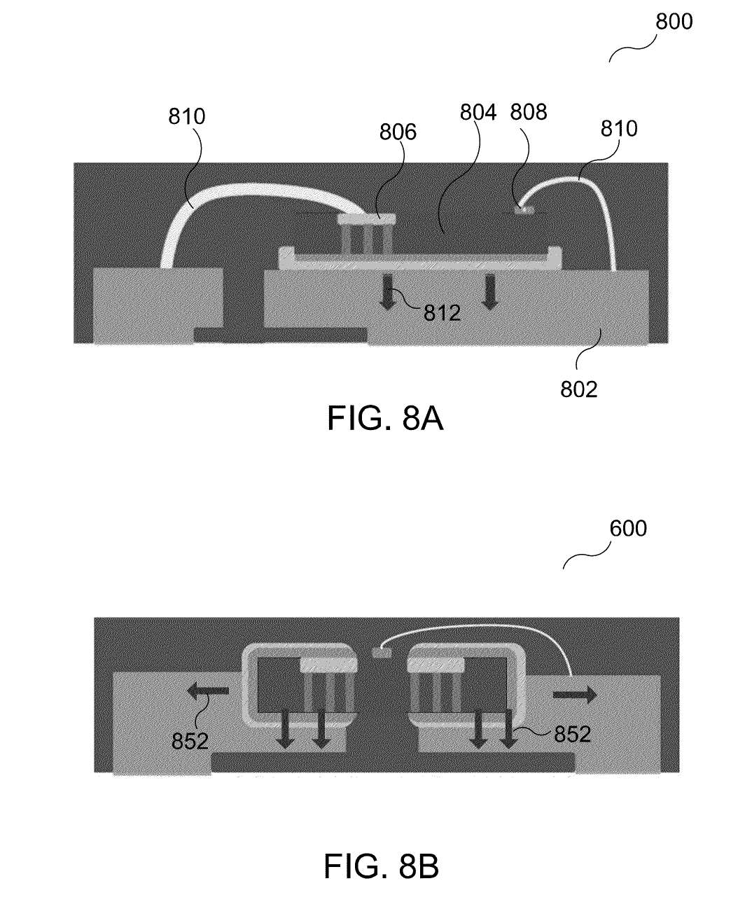

The chip and the chip arrangement according to various embodiments above provide improved electrical and thermal performance, as shown in FIG. 8A and FIG. 8B below.

FIG. 8A shows an existing chip package 800, including a chip 804 arranged over a chip carrier 802. The chip 804 includes a power electrode 806 and a control electrode 808 on its main surface, which are re-distributed or re-wired to the chip carrier through the bond wires 810.

FIG. 8B shows a chip package 600 according to various embodiments, as described in FIG. 6 above.

Compared with the chip package 800 wherein both the power electrode 806 and the control electrode 808 are re-distributed by bond wires 810, the chip package 600 of various embodiments redistributes both power electrodes by means of the leadframe and redistributes the control electrode by means of a bond wire, thereby allowing an improvement of electrical and thermal performance over the chip package 800. For example, compared with the chip package 800 wherein the thermal dissipation is only in the downward direction as depicted by arrows 812, the chip package 600 may allow thermal dissipation in both downward and lateral directions as depicted by arrows 852.

According to various embodiments above, the chip redistribution is implemented in a three-dimensional (3D) manner, e.g. by extending the power electrodes over the main surface and the side surface of the chip body and by further re-distribution via the leadframe. By means of 3D chip redistribution, both electrical and thermal performance of the chip and the chip arrangement may be improved, since both power electrodes are arranged symmetrically over the chip surfaces. Based on the symmetric arrangement, the leadframe re-distribution or re-wiring for both power electrodes may be used and thus the total electro-thermal performance may be optimized. The chip and the chip arrangement of various embodiments with the 3D re-distribution may improve the chip re-distribution or re-wiring electrically and thermally for power packages.

According to various embodiments above, 3D chip-redistribution with symmetric power electrodes may be provided. According to various embodiments above, 3D chip-redistribution with both electrodes on both chip surfaces (main surface and side surface) are provided. The 3D chip-redistribution of various embodiments may be used for various power components or power chips, and may be used with structured leadframe.

In various embodiments, 3D coverage over all side surfaces may be possible. For example, though FIGS. 2 to 7 show two side surfaces at the left and right side of the body, it is understood that the first power electrode and/or the second power electrode may also extend over the other two surfaces of the body perpendicular to the left and the right side surfaces.

The re-distribution on a bare chip or a bare die according to various embodiments above, e.g. by extending the power electrodes via the solderable layer, may also provide protection for the chip.

In various embodiments, the chip 200, 300 and the chip arrangement 400, 500, 600, 700 described in various embodiments above may be used for a standard chip package or an embedded chip package.

In various embodiments, the chip 200, 300 and the chip arrangement 400, 500, 600, 700 having symmetric power electrodes as described in various embodiments above may be contacted or connected directly on a substrate or a board by means of wave soldering or reflow soldering, in a comparable manner to existing SMD (surface-mounted-device) packages (e.g. PowerCSP chip-scale package).

In various embodiments, the chip 200, 300 and the chip arrangement 400, 500, 600, 700 described in various embodiments above may be used for multi-chip-modules, which may include, e.g. a half bridge circuit or a cascade circuit formed by multiple chips.

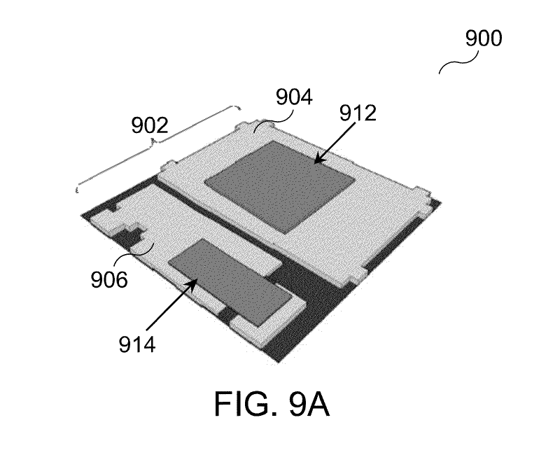

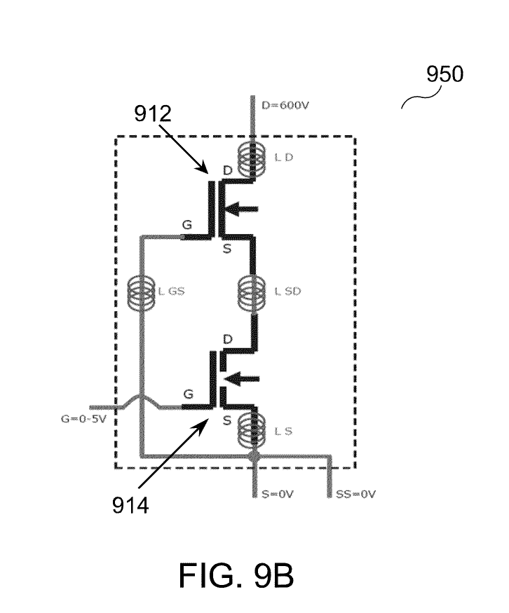

FIG. 9A shows a chip arrangement 900 according to various embodiments.

As shown in FIG. 9A, a chip carrier 902 may be a leadframe, and may include a first leadframe part 904 and a second leadframe part 906. A first chip 912, e.g. a GaN HEMT chip, may be arranged over the first leadframe part 904; and a second chip 914, e.g. a SFET chip, may be arranged over the second leadframe part 906.

Each of the first chip 912 and the second chip 914 may be the chip 200 of FIG. 2 or the chip 300 of FIG. 3 described above. Accordingly, the source electrode and the drain electrode of the GaN HEMT chip 912 may face away from the first leadframe part 904, and may extend over at least one main surface and at least one side surface of the chip body. The source electrode and the drain electrode of the SFET chip 914 may face away from the second leadframe part 906, and may extend over at least one main surface and at least one side surface of the chip body.

In various embodiments, the source electrode of the GaN HEMT chip 912 may be electrically coupled with the drain electrode of the SFET chip 914, e.g. through electrical coupling of respective leads or respective portions of the leadframe 902 re-wired to the source electrode of the GaN HEMT chip 912 and the drain electrode of the SFET chip 914. In various embodiments, the gate electrode of the GaN HEMT chip 912 may be electrically coupled with the source electrode of the SFET chip 914, e.g. through a bond wire connected between the gate electrode of the GaN HEMT chip 912 and the source electrode of the SFET chip 914. The GaN HEMT chip 912 and the SFET chip 914 with such electrical coupling may form a cascade circuit as described below.

The electrical coupling among the power electrodes and control electrodes of the chips 912, 914, though not shown in detail in FIG. 9A, can be carried out through respective leads or respective portions of the leadframe or bond wires shown in the structure of the chips 200, 300 and the chip arrangement 400, 500, 600, 700 above.

In various embodiments, the chip carrier 902 may include various number of leadframe parts, depending on the required connection between the chips 912, 914 or the number of chips included in the chip arrangement 900.

In the embodiments described with reference to FIG. 9A, the GaN chip 912 may be a high voltage (e.g. larger than 200V) HEMT switch and the SFET chip 914 may be a low voltage (e.g. smaller than 200V) power MOSFET. The GaN HEMT 912 is a normally-on device, and is transformed to a normally-off transistor with introducing of the low-voltage SFET 914. Such a GaN-SFET arrangement may correspond to the cascade circuit 950 of FIG. 9B.

The cascade circuit 950 may include a low voltage SFET 914 in common-source and a high voltage GaN-HEMT 912 in common-gate configuration. The resulting 3-port circuit may act as a switch. The drain electrode of the GaN-HEMT 912 is defining the 600V behavior of the cascade circuit 950.

The chips 912, 914 may also be connected differently to form other types of circuit instead of the cascade circuit 950 of FIG. 9B.

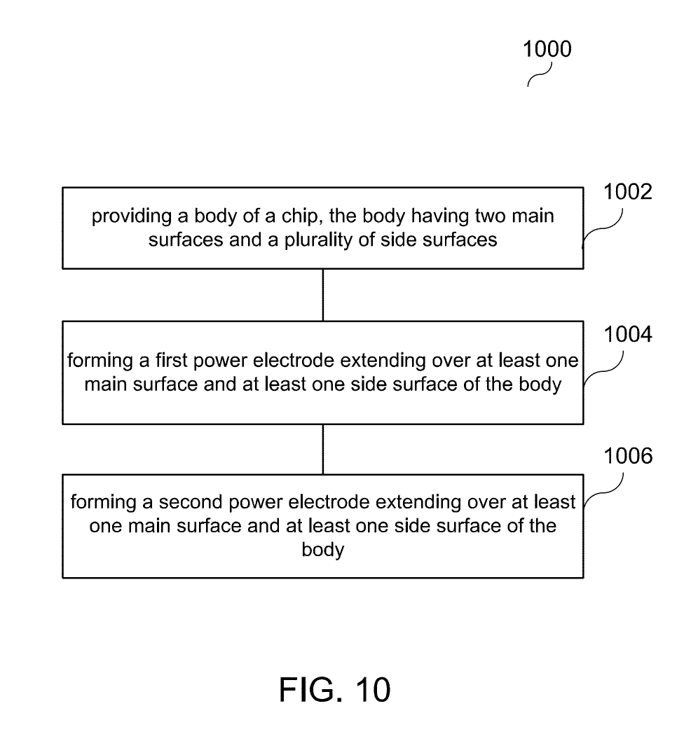

FIG. 10 shows a flowchart 1000 illustrating a method of manufacturing a chip according to various embodiments.

At 1002, a body of a chip may be provided, wherein the body includes two main surfaces and a plurality of side surfaces.

At 1004, a first power electrode may be formed extending over at least one main surface and at least one side surface of the body.

At 1006, a second power electrode may be formed extending over at least one main surface and at least one side surface of the body.

In various embodiments, at least one of the first power electrode and the second power electrode may be formed extending over at least a portion of a plurality of the side surface of the body.

In various embodiments, at least one of the first power electrode and the second power electrode may be formed extending over a portion of both main surfaces of the body.

In various embodiments, the first power electrode and the second power electrode may be formed in a symmetric arrangement.

In various embodiments, a control electrode of the chip may be formed. The control electrode and both power electrodes may be formed on the same main surface of the body, or the control electrode may be arranged on the other main surface of the body than the power electrodes.

Various embodiments described in the context of the chip above are analogously valid for the method of manufacturing a chip.

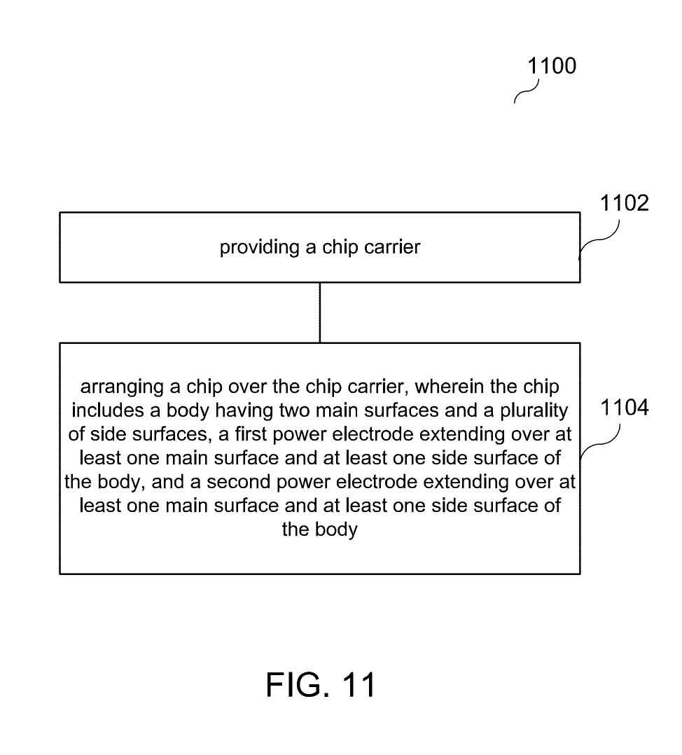

FIG. 11 shows a flowchart 1100 illustrating a method of manufacturing a chip arrangement according to various embodiments.

At 1102, a chip carrier may be provided.

At 1104, a chip may be arranged over the chip carrier. The chip may include a body having two main surfaces and a plurality of side surfaces; a first power electrode extending over at least one main surface and at least one side surface of the body; and a second power electrode extending over at least one main surface and at least one side surface of the body.

In various embodiments, encapsulating material may be formed encapsulating the chip carrier and the chip.

Various embodiments described in the context of the chip arrangement above are analogously valid for the method of manufacturing a chip arrangement.

Various embodiments provide a chip. The chip may include a body having two main surfaces and a plurality of side surfaces. The chip may further include a first power electrode extending over at least one main surface and at least one side surface of the body; and a second power electrode extending over at least one main surface and at least one side surface of the body.

In various embodiments, at least one of the first power electrode and the second power electrode may extend over at least a portion of a plurality of the side surface of the body.

In various embodiments, at least one of the first power electrode and the second power electrode may extend over a portion of both main surfaces of the body.

In various embodiments, at least one of the first power electrode and the second power electrode may extend over at least one main surface and at least one side surface of the body through a solderable layer.

In various embodiments, the first power electrode and the second power electrode may have a symmetric arrangement.

At least one of the first power electrode and the second power electrode may be made of a metal selected from a group of metals consisting of: Cu, Ni, Ti, Au, Ag, Pd, Pt, W.

According to various embodiments, the chip may be configured as a power transistor.

In various embodiments, the chip may further include a control electrode of the power transistor. In various embodiments, the control electrode and both power electrodes may be arranged on the same main surface of the body. In various embodiments, the control electrode may also be arranged on the other main surface of the body than the power electrodes

According to various embodiments, the chip may be configured as a power field effect transistor, e.g., a power MOSFET (metal oxide semiconductor field effect transistor) or a JFET (junction field effect transistor). The first power electrode may be a source electrode, the second power electrode may be a drain electrode, and the control electrode may be a gate electrode.

According to various embodiments, the chip may be configured as a bipolar transistor. The first power electrode may be an emitter electrode, the second power electrode may be a collector electrode, and the control electrode may be a base electrode.

According to various embodiments, the chip may be configured as an insulated gate bipolar transistor (IGBT). The first power electrode may be an emitter electrode, the second power electrode may be a collector electrode, and the control electrode may be a gate electrode.

In various embodiments, the chip may be configured as various power components, such as High Electron Mobility Transistors (HEMT), e.g., GaN (Gallium Nitride) HEMT, SiC (Silicon Carbide) HEMT, or High-voltage Si (Silicon) HEMT; or low-voltage (e.g., smaller than 200V) MOSFET (p-channel or n-channel), e.g. SFET (silicon field effect transistor).

According to various embodiments, the chip may further include a plurality of through holes or vias extending from at least one of the first power electrode and the second power electrode 214 through the body to the other main surface of the body.

Various embodiments provide a chip arrangement. The chip arrangement may include a chip carrier and a chip arranged over the chip carrier. The chip may include a body having two main surfaces and a plurality of side surfaces; a first power electrode extending over at least one main surface and at least one side surface of the body; and a second power electrode extending over at least one main surface and at least one side surface of the body.

Various embodiments of the chip described above are analogously valid for the chip arrangement.

In various embodiments, at least one of the first power electrode and the second power electrode may extend over at least one main surface and at least one side surface of the body through a solderable layer. In various embodiments, the chip may be attached to the chip carrier through a solder layer. In various embodiments, the solder layer may be formed over the solderable layer of the chip, so as to attach the chip to the chip carrier.

According to various embodiments, the chip carrier may be one of an FR4 substrate; a direct copper bond (DCB) substrate; and an isolated metal substrate (IMS).

In various embodiments, the chip carrier may be a leadframe. The leadframe may be made of a metal or a metal alloy, e.g. including a material selected from a group consisting of: copper (Cu), iron nickel (FeNi), steel, and the like. In various embodiments, the chip carrier may be a structured leadframe. The leadframe may be structured to include a plurality of portions or blocks separate from each other, and/or may be structured to provide a desired creepage distance.

According to various embodiments, the chip may be a bare chip, e.g. an integrated circuit cut out from the wafer and is ready for packaging.

In various embodiments, the chip arrangement may further include encapsulating material encapsulating the chip carrier and the chip.

Various embodiments provide a method of manufacturing a chip. The method may include providing a body of a chip, wherein the body includes two main surfaces and a plurality of side surfaces. The method may further include forming a first power electrode extending over at least one main surface and at least one side surface of the body; and forming a second power electrode extending over at least one main surface and at least one side surface of the body.

In various embodiments, at least one of the first power electrode and the second power electrode may be formed extending over at least a portion of a plurality of the side surface of the body.

In various embodiments, at least one of the first power electrode and the second power electrode may be formed extending over a portion of both main surfaces of the body.

In various embodiments, the first power electrode and the second power electrode may be formed in a symmetric arrangement.

In various embodiments, a control electrode of the chip may be formed. The control electrode and both power electrodes may be formed on the same main surface of the body, or the control electrode may be arranged on the other main surface of the body than the power electrodes.

Various embodiments provide a method of manufacturing a chip arrangement. The method may include providing a chip carrier, and arranging a chip over the chip carrier. The chip may include a body having two main surfaces and a plurality of side surfaces; a first power electrode extending over at least one main surface and at least one side surface of the body; and a second power electrode extending over at least one main surface and at least one side surface of the body.

In various embodiments, encapsulating material may be formed encapsulating the chip carrier and the chip.

Various embodiments described in the context of the chip or the chip arrangement above are analogously valid for the method of manufacturing a chip or a chip arrangement.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A chip, comprising:
a body comprising two main surfaces and a plurality of side surfaces;
a first power electrode extending over at least one main surface and at least one side surface of the body;
a second power electrode extending over at least one main surface and at least one side surface of the body.

2. The chip of claim 1,
wherein at least one of the first power electrode and the second power electrode extend over at least a portion of a plurality of the side surface of the body.

3. The chip of claim 1,
wherein at least one of the first power electrode and the second power electrode extend over a portion of both main surfaces of the body.

4. The chip of claim 1,
wherein the first power electrode and the second power electrode have a symmetric arrangement.

5. The chip of claim 1,
wherein at least one of the first power electrode and the second power electrode are made of a metal selected from a group of metals consisting of: Cu, Ni, Ti, Au, Ag, Pd, Pt, W.

6. The chip of claim 1,
configured as a power transistor.

7. The chip of claim 6, further comprising:
a control electrode of the power transistor.

8. The chip of claim 7,
wherein the control electrode and both power electrodes are arranged on the same main surface of the body.

9. The chip of claim 7,
wherein the control electrode is arranged on the other main surface of the body than the power electrodes.

10. The chip of claim 7,
configured as a power field effect transistor;
wherein the first power electrode is a source electrode and the second power electrode is a drain electrode; and
wherein the control electrode is a gate electrode.

11. The chip of claim 7,
configured as a bipolar transistor;
wherein the first power electrode is an emitter electrode and the second power electrode is a collector electrode; and
wherein the control electrode is a base electrode.

12. A chip arrangement, comprising:
a chip carrier; and
a chip arranged over the chip carrier, comprising:
a body comprising two main surfaces and a plurality of side surfaces;
a first power electrode extending over at least one main surface and at least one side surface of the body;
a second power electrode extending over at least one main surface and at least one side surface of the body.

13. The chip arrangement of claim 12,
wherein the chip is a bare chip.

14. The chip arrangement of claim 12,
wherein the chip carrier is one of an FR4 substrate; a DCB; and an isolated metal substrate (IMS).

15. The chip arrangement of claim 12, further comprising:
encapsulating material encapsulating the chip carrier and the chip.

16. The chip arrangement of claim 12,
wherein the chip carrier is a leadframe.

17. The chip arrangement of claim 16,
wherein the leadframe is a structured leadframe.

18. A method for manufacturing a chip, the method comprising:
providing a body comprising two main surfaces and a plurality of side surfaces;
forming a first power electrode extending over at least one main surface and at least one side surface of the body;
forming a second power electrode extending over at least one main surface and at least one side surface of the body.

19. The method of claim 18, further comprising:
forming at least one of the first power electrode and the second power electrode extending over at least a portion of a plurality of the side surface of the body.

20. The method of claim 18, further comprising:
forming at least one of the first power electrode and the second power electrode extending over a portion of both main surfaces of the body.

21. The method of claim 18, further comprising:
forming the first power electrode and the second power electrode in a symmetric arrangement.

22. The method of claim 18, further comprising:
forming a control electrode.

23. The method of claim 22, further comprising:
arranging the control electrode and both power electrodes on the same main surface of the body.

24. The method of claim 22, further comprising:
arranging the control electrode on the other main surface of the body than the power electrodes.

25. A method for manufacturing a chip arrangement, the method comprising:
providing a chip carrier; and
arranging a chip arranged over the chip carrier, the chip comprising:
a body comprising two main surfaces and a plurality of side surfaces;
a first power electrode extending over at least one main surface and at least one side surface of the body;
a second power electrode extending over at least one main surface and at least one side surface of the body.
